(19) United States
(12) Patent Application Publication
(10) Pub. No.: US 2012/0237059 A1
(43) Pub. Date: Sep. 20, 2012

(54) ELECTRONIC APPARATUS

(75) Inventor: Kazuyuki SAITO, Ome-shi (JP)

(73) Assignee: KABUSHIKI KAISHA TOSHIBA, Tokyo (JP)

(21) Appl. No.: 13/485,564

(22) Filed: May 31, 2012

Related U.S. Application Data
(63) Continuation of application No. 12/955,660, filed on Nov. 29, 2010.

(30) Foreign Application Priority Data
Nov. 30, 2009 (JP) 2009-272775

(51) Int. Cl. H03F 99/00

(52) U.S. Cl. 381/120

(57) ABSTRACT

According to one embodiment, an electronic apparatus includes a terminal, an amplifier, a speaker, a power supply circuit, a first switch and a first controller. The terminal configured to input an audio signal from an external device. The amplifier configured to amplify the audio signal which is input from the terminal. The speaker configured to output sound corresponding to the audio signal which is amplified by the amplifier. The power supply circuit connected to the amplifier. The first controller configured to control the power supply circuit in order to supply the power to the amplifier, when the electronic apparatus is in a non-operative state and the first switch is turned on.

### CROSS-REFERENCE TO RELATED APPLICATIONS

This application is a continuation of U.S. patent application Ser. No. 12/955,660, filed on Nov. 29, 2010, which is based upon and claims the benefit of priority from Japanese Patent Application No. 2009-272775, filed Nov. 30, 2009; the entire contents of these applications are incorporated herein by reference.

### FIELD

Embodiments described herein relate generally to an electronic apparatus having a speaker.

### BACKGROUND

Conventionally, there is known a portable computer in which a disc player is built, wherein a playback/listening operation of a signal by head phones can be independently performed. Jpn. Pat. Appln. KOKAI Publication No. H10-340517 discloses a portable computer wherein when a plug of headphones is inserted in a headphone jack, power is supplied to a disc player module, a playback circuit for headphones and an operation switch module, thereby being able to perform a playback/listening operation by headphones, regardless of a change-over operation of a power switch for supplying power to a computer circuit module.

In the prior art, as described above, the playback/listening operation by the headphones can be performed regardless of the change-over operation of the power switch. However, the portable computer needs to be activated as a disc player, since it is necessary to perform operations corresponding to a replay operation switch, a song-selection operation switch, a quick forward operation switch and a stop operation switch which are provided on the operation switch module.

In addition, in the prior art, the portable computer is simply caused to operate as a disc player, and it is not possible to input an audio signal from an external music playback device (e.g. portable audio player), and to output the audio signal from headphones.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary external appearance view showing the structure of an electronic apparatus according to an embodiment;

FIG. 2 is an exemplary block diagram showing the system configuration of a personal computer according to the embodiment;

FIG. 3 is an exemplary view showing powers which are supplied in the respective states (system states) of the personal computer according to the embodiment;

FIG. 4 is an exemplary view showing the transition of the state (system state) of the personal computer according to the embodiment;

FIG. 5 is an exemplary flow chart illustrating the operation of the personal computer according to the embodiment;

FIG. 6 is an exemplary flow chart illustrating the operation of the personal computer according to the embodiment;

FIG. 7 is an exemplary view showing modules which are supplied with power when power is turned on in the embodiment;

FIG. 8 is an exemplary view showing modules which are supplied with power at a time of a standby mode without insertion of a plug in the embodiment;

FIG. 9 is an exemplary view showing modules which are supplied with power at a time of a standby mode with the plug being inserted in the embodiment;

FIG. 10 is an exemplary view showing a module which is supplied with power at a time of power-off without insertion of the plug in the embodiment; and

FIG. 11 is an exemplary view showing modules which are supplied with power at a time of power-off with the plug being inserted in the embodiment.

### DETAILED DESCRIPTION

Various embodiments will be described hereinafter with reference to the accompanying drawings.

In general, according to one embodiment, a electronic apparatus includes a terminal, an amplifier, a speaker, a power supply circuit, a first switch and a first controller. The terminal configured to input an audio signal from an external device. The amplifier configured to amplify the audio signal which is input from the terminal. The speaker configured to output sound corresponding to the audio signal which is amplified by the amplifier. The power supply circuit connected to the amplifier. The first controller configured to control the power supply circuit in order to supply the power to the amplifier, when the electronic apparatus is in a non-operative state and the first switch is turned on.

An embodiment will now be described with reference to the accompanying drawings.

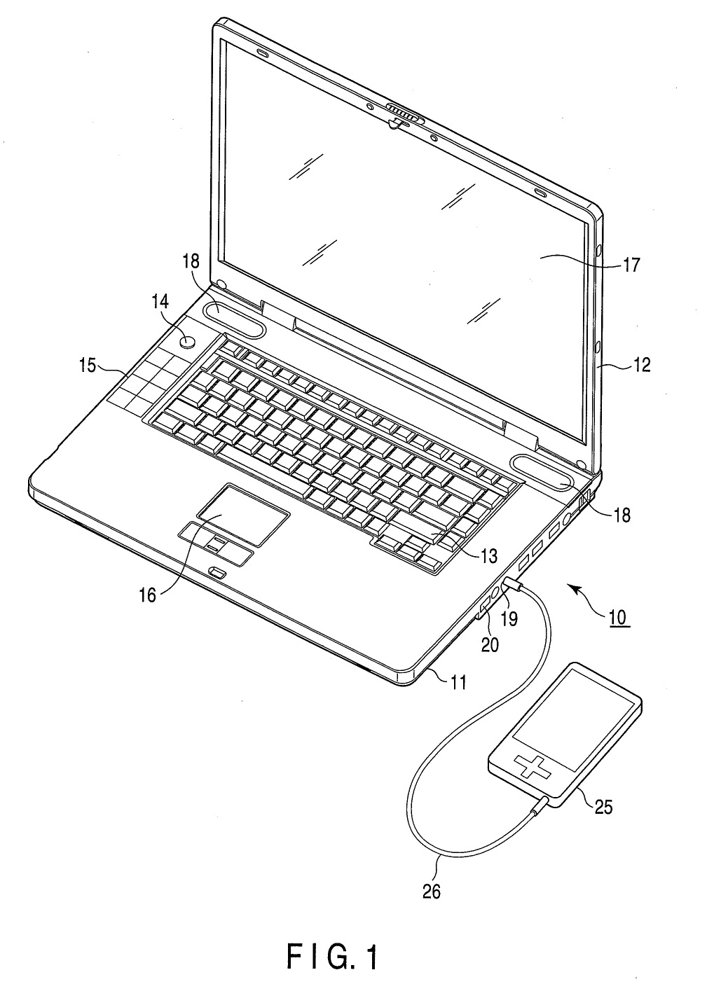

FIG. 1 shows the external appearance of an electronic apparatus according to the present embodiment. The electronic apparatus is realized, for example, as a notebook-type portable personal computer 10. The personal computer 10 of this embodiment has an audio output function (sleep & music function) for receiving, at a time of a non-operative state, an analog audio signal which is output from a line output-equipped external device (e.g. a portable audio player 25), and outputting the audio signal from speakers 18 which are mounted on the housing of the computer 10.

In the case where the output from the audio player 25 is directly connected to the speakers, since the output of the audio player 25 is small, compared to the capability of the speakers, the speakers are unable to output sound of a sufficient volume. According to the audio output function that is provided in the personal computer 10 in this embodiment, even in the case where the personal computer 10 is in the non-operative state, power is supplied to a built-in amplifier for audio signal amplification, thus being able to amplify the audio signal from the audio player 25 and output the amplified audio signal from the speakers.

It is assumed that the “non-operative state” of the personal computer 10 includes states called “standby/sleep/suspend” and “hibernation” (hibernate state), as well as a power-off state. In short, the non-operative state is a state in which the processor (CPU 30) does not operate.

FIG. 1 is a perspective view showing the state in which a display unit of the personal computer 10 is opened. The personal computer 10 comprises a computer main body 11 and a display unit 12. A display device, which is composed of an LCD (Liquid Crystal Display) 17, is built in the display unit 12. The display screen of the LCD 17 is disposed at a substantially central part of the display unit 12.

The display unit 12 is attached to the computer main body 11 such that the display unit 12 is rotatable between an open position and a closed position, relative to the computer main body 11. The computer main body 11 has a thin box-shaped housing, to which a battery is detachably attached.

A keyboard 13, a power button switch 14 for power-on/power-off, general-purpose hardware buttons 15, a touch pad 16, and speakers 18 are disposed on the top surface of the computer main body 11.

A side surface of the computer main body 11 is provided with a line-in terminal 19 (jack) for receiving an analog audio signal which is output from the audio player 25, and a volume dial 20 which is used for volume control in the case where the audio output function is enabled at the time of the non-operative state. A cable 26, which is connected to a line-out terminal of the audio player 25, can be connected to the line-in terminal 19.

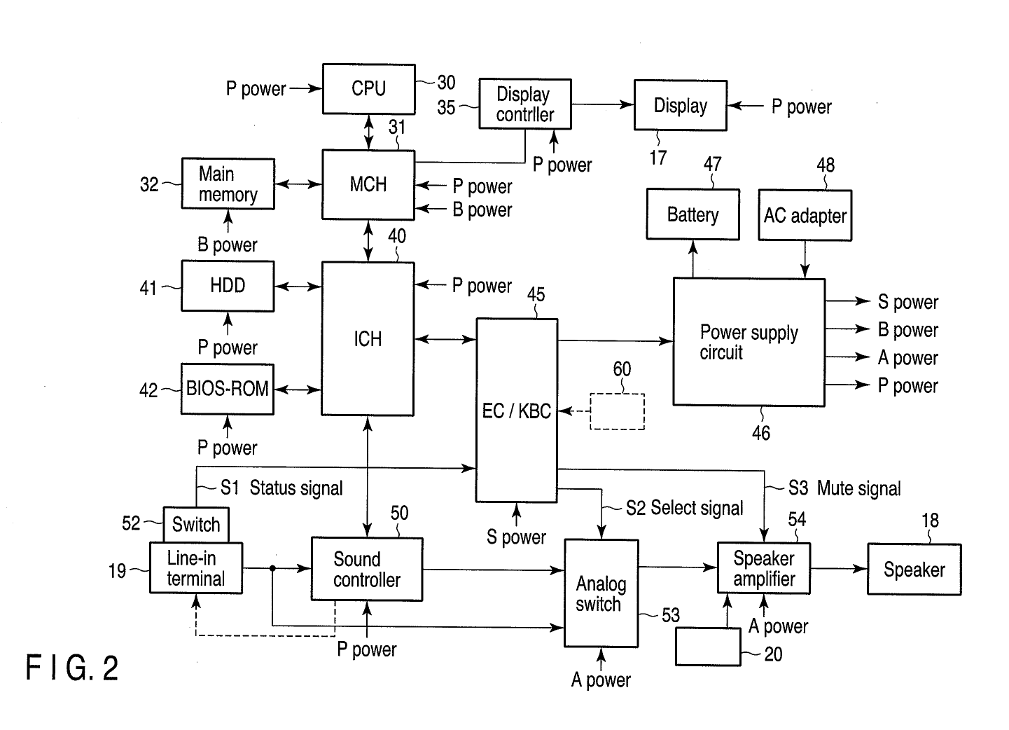

Next, referring to FIG. 2, a description is given of the system configuration of the personal computer 10 according to the embodiment.

The personal computer 10, as shown in FIG. 2, includes a CPU 30, an MCH 31 (north bridge), a main memory 32, a display controller 35, an ICH 40 (south bridge), a hard disk drive (HDD) 41, a BIOS-ROM 42, an embedded controller/keyboard controller IC (EC/KBC) 45, and a power supply circuit 46.

The CPU 30 is a processor which is provided in order to control the operation of the personal computer 10, and executes an operating system (OS), drivers for controlling various hardware, and various application/utility programs, which are loaded from the HDD 41 into the main memory 32. The CPU 30 also executes a system BIOS (Basic Input/Output System) which is stored in the BIOS-ROM 42. The system BIOS is a program for hardware control.

The MCH 31 is a bridge device which connects a local bus of the CPU 30 and the ICH 40. The MCH 31 incorporates a memory controller for access-controlling the main memory 32.

The display controller 35 controls the LCD 17 which is used as a display monitor of the personal computer 10. On the basis of an image-rendering request which is sent from the CPU 30 via the MCH 31, the display controller 35 executes a display process (graphics arithmetic process) for rendering frames in a video memory (VRAM).

The ICH 40 incorporates an IDE (Integrated Drive Electronics) controller and a Serial ATA controller for controlling the HDD 41 and an optical disc drive (not shown).

The embedded controller/keyboard controller IC (EC/KBC) 45 is a 1-chip microcomputer in which an embedded controller for power management and a keyboard controller for controlling the keyboard (KB) 13, touch pad 15 and general-purpose hardware buttons 18 are integrated.

The EC/KBC 45 has a function of controlling the power supply circuit 46 in accordance with an operation of the power button switch 14 by a user, and powering on/off the personal computer 10. The power-on/off control of the personal computer 10 is executed by the cooperation between the EC/KBC 45 and power supply circuit 46. In addition, the EC/KBC 45 controls the audio output function which is used when the personal computer 10 is in the non-operative state.

The power supply circuit 46 receives power from a battery 47 which is attached to the computer main body 11 or from an external power supply which is connected via an AC adapter 48, and generates and supplies operation power to the respective components. The power supply circuit 46 is provided with a power supply microcomputer. The power supply microcomputer monitors the power supply (charge/discharge) relating to the respective components and the battery, and the charging state of the battery.

The power supply circuit 46 switches the power supply to the respective modules by the control of the EC/KBC 45, in accordance with the system state of the personal computer 10. By the control of the EC/KBC 45 according to the system state of the personal computer 10, the power supply circuit 46 can turn on/off the power supply of power supply systems of an S power, a B power, an A power and a P power.

The S power is a power which is always supplied even in the state in which the system is powered off, and is supplied to the EC/KBC 45.

The B power is a power which is supplied in a standby state in order to back up data which is recorded in the main memory 32.

The A power is a power for enabling the audio output function when the personal computer 10 is in the non-operative state, and is supplied to an analog switch 53 and a speaker amplifier 54, which process an analog audio signal.

The P power is a power which is supplied when the personal computer 10 is in the power-on state.

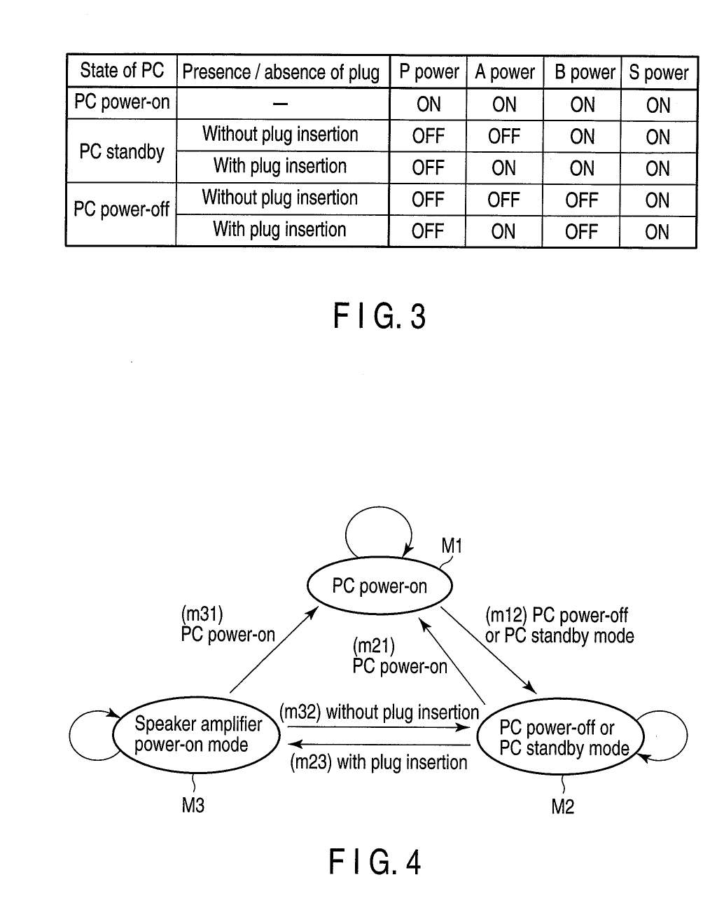

FIG. 3 shows powers which are supplied in the respective states (system states) of the personal computer 10.

As shown in FIG. 3, in the case where the personal computer 10 is in the power-on state (operative state), the power supply circuit 46 turns on power supply of all of the S power, B power, P power and A power.

In the case where the personal computer 10 is in the standby state (or in the sleep/suspend state), the power supply of the S power and B power is turned on. However, in the personal computer 10 of the present embodiment, in the case where the plug for connection of the cable 26 (portable audio player 25) is inserted in the line-in terminal 19 in order to use the audio output function in the standby state, the supply of the A power is further turned on, thereby supplying power to the analog switch 53 and speaker amplifier 54 which are operated in the audio output function.

In the case where the personal computer 10 is in the power-off state (including the hibernation (hibernate state) in which backup for the main memory 32 is unnecessary), only the supply of the S power is turned on. However, in the personal computer 10 of the present embodiment, in the case where the plug for connection of the cable 26 (portable audio player 25) is inserted in the line-in terminal 19 in order to use the audio output function in the power-off state, the supply of the A power is further turned on, thereby supplying power to the analog switch 53 and speaker amplifier 54 which are operated in the audio output function.

Since the S power is supplied to the EC/KBC 45, the power supply is turned on in any one of the system states and the control of the audio output function at the non-operation time is enabled.

The sound controller 50 (audio codec) converts digital audio data, which is input via the ICH 40, to an analog audio signal, and outputs the analog audio signal to the analog switch 53 by executing volume control by the control of the OS, device driver, audio playback program, etc. Similarly, when the personal computer 10 is in the operative state, the sound controller 50 executes volume control of an analog audio signal from the audio player 25, which is input via the line-in terminal 19, and outputs the resultant analog audio signal to the analog switch 53.

The analog switch 53 switches the path between the sound controller 50 side and the line-in terminal 19 side, in accordance with a select signal S2 from the EC/KBC 45. Under the control of the EC/KBC 45, the analog switch 53 is changed over to the sound controller 50 side when the personal computer 10 is in the operative state. In the case where the audio output function is enabled at the non-operation time, the analog switch 53 is changed over to the line-in terminal 19 side, with the sound controller 50 being bypassed.

The speaker amplifier 54 amplifies the analog audio signal which is input via the analog switch 53, and outputs sound corresponding to the audio signal from the speaker 18. In addition, in the case where the audio output function is enabled, the speaker amplifier 54 executes volume control for the audio signal, in accordance with the operation of the volume dial 20.

A switch 52 is incorporated in the line-in terminal 19. The ON/OFF of the switch 52 is changed by the insertion of the plug for connection of the cable 26 in the line-in terminal 19, and the switch 52 outputs a status signal S1 corresponding to the ON/OFF state to the EC/KBC 45.

Next, the operation of the personal computer 10 according to the present embodiment is described.

In the case where the personal computer 10 of the embodiment is in the non-operative state such as the power-off state or standby mode, when the plug for connection of the cable 26 is inserted in the line-in terminal 19, the power supply to the speaker amplifier 54 (the supply of the A power) is turned on, and the analog switch 53 is changed over to bypass the sound controller 50. Thereby, without activating the personal computer 10, the speakers 18 built in the personal computer 10 produce sound (music) of the audio signal which is output from the portable audio player 25.

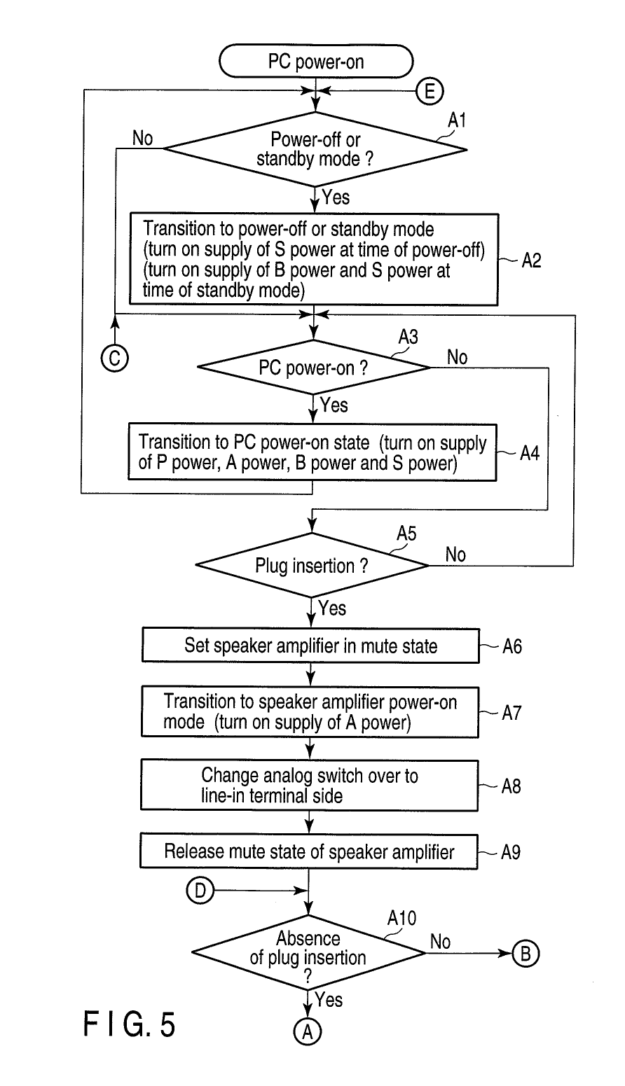

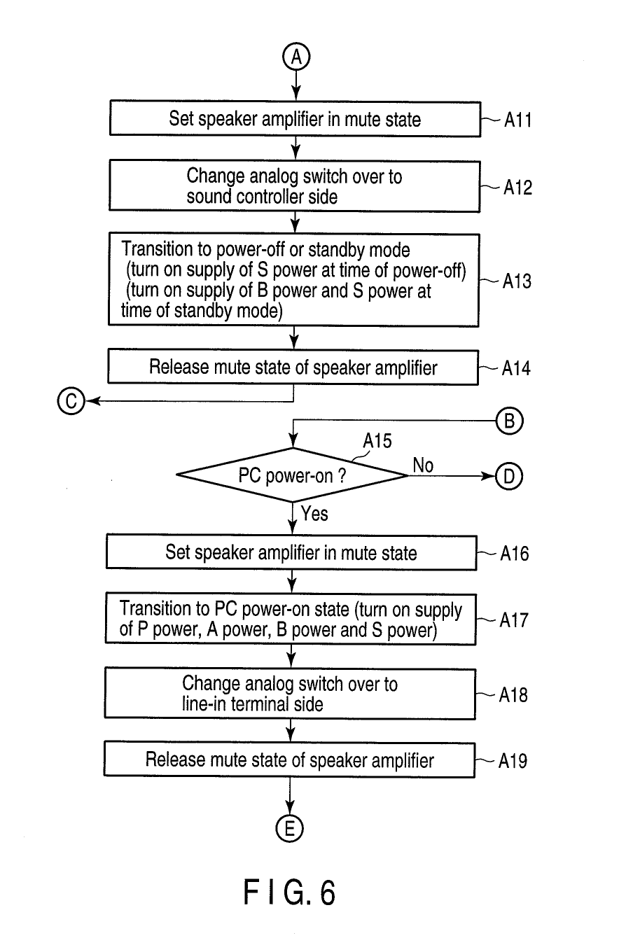

FIG. 4 shows the transition of the state (system state) of the personal computer 10 according to the embodiment. FIG. 5 and FIG. 6 are flow charts illustrating the operation of the personal computer 10.

If power-on of the personal computer 10 is instructed by the operation of the power button switch 14 (Yes in block A3), power is supplied from the power supply circuit 46 to the respective modules by the control of the EC/KBC 45 (block A4). In the power-on state, the power supply circuit 46 turns on the power supply of all the S power, B power, P power and A power (state M1 in FIG. 4).

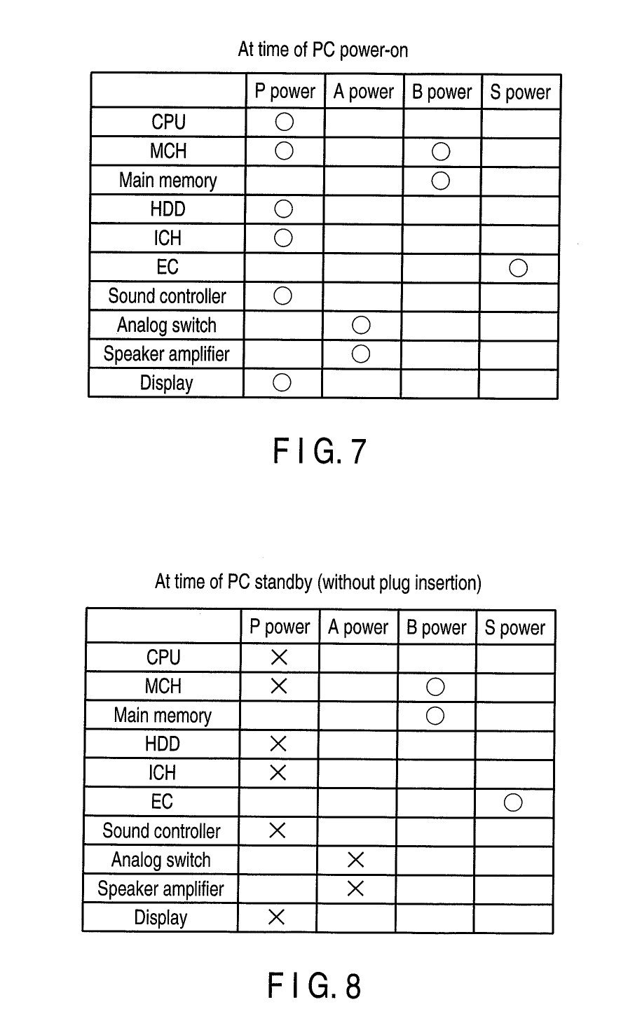

FIG. 7 shows modules to which power is supplied at the time of power-on. As shown in FIG. 7, power is supplied to the CPU 30, MCH 31, ICH 40, main memory 32, HDD 41, sound controller 50, analog switch 53, speaker amplifier 54, etc. At the time of power-on, the EC/KBC 45 changes the analog switch 53 over to the sound controller 50 side by the select signal S2.

As regards the audio process, the OS, device drivers, software program, etc. operate to control the respective modules. By the control of the program, the sound controller 50 converts digital audio data to an analog audio signal, and outputs the analog audio signal to the analog switch 53. The speaker amplifier 54 amplifies the analog audio signal, which is input via the analog switch 53, and outputs sound from the speakers 18.

In addition, the sound controller 50 also executes volume control for the analog audio signal which is input from the line-in terminal 19, and outputs the resultant analog audio signal to the analog switch 53. Similarly, the speaker amplifier 54 amplifies the analog audio signal which is input from the analog switch 53, and outputs sound from the speakers 18.

If a transition to the standby mode is instructed by the user (Yes in block A1), the EC/KBC 45 instructs the power supply circuit 46 to turn off the supply of the P power. Specifically, if the transition is made to the standby mode (m12 in FIG. 4), the supply of only the B power and S power is turned on (state M2 in FIG. 4). FIG. 8 shows modules to which power is supplied at the time of the standby mode without plug insertion. As shown in FIG. 8, the power supply to many modules including the CPU 30 is turned off in the standby mode with reduced power consumption. In the standby mode, since the CPU 30 does not operate, a program cannot be executed.

At this time, if the plug is inserted in the line-in terminal 19, the switch 52 built in the line-in terminal 19 is turned on and the status signal S1, which is supplied to the EC/KBC 45, is set in a Low state. On the basis of the status signal S1, the EC/KBC 45 detects that the plug is inserted in the line-in terminal 19. If the EC/KBC 45 detects the insertion of the plug (Yes in block A5) (m23 in FIG. 4), the EC/KBC 45 sets the speaker amplifier 54 in a mute state by a mute signal S3, prior to effecting a transition to a speaker amplifier power-on mode for enabling the audio output function (block A6). Specifically, since noise occurs when power is supplied to the speaker amplifier 54 or when the analog switch 53 is changed over, the speaker amplifier 54 is controlled to prevent the speakers 18 from producing sound.

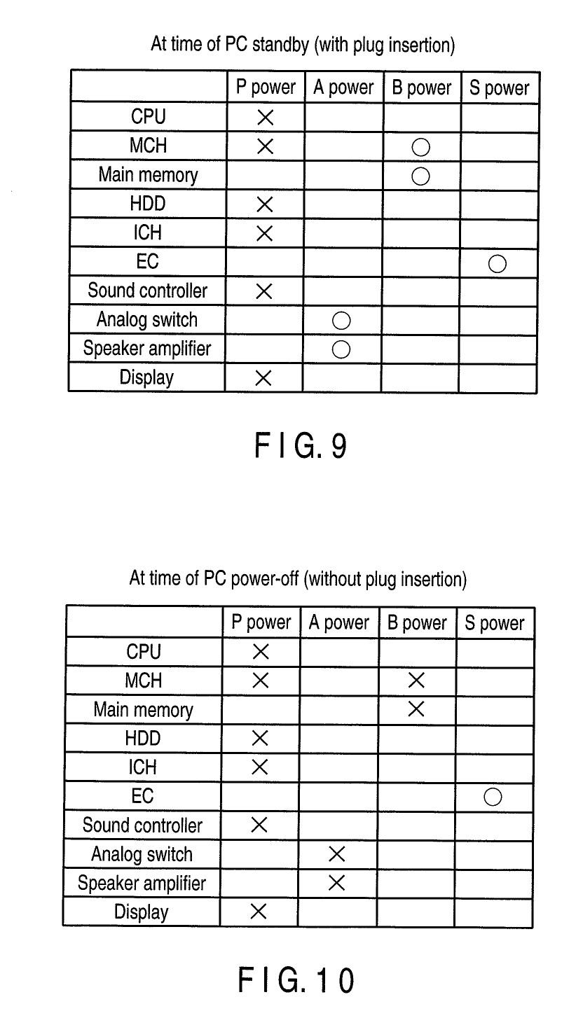

After the speaker amplifier 54 is set in the mute state, the EC/KBC 45 causes the power supply circuit 46 to turn on the supply of the A power (block A7), thus effecting a transition to the speaker amplifier power-on mode (state M3 in FIG. 4). FIG. 9 shows modules to which power is supplied at the time of the standby mode with plug insertion. As shown in FIG. 9, while power supply to many modules including the CPU 30 is turned off in the standby mode with reduced power consumption, the A power is supplied to only the speaker amplifier 54 and analog switch 53 which are associated with the audio output function.

The sound controller 50 does not operate in the standby mode which is controlled by the program. Thus, the EC/KBC 45 controls the analog switch 53 by the select signal S2, thereby to switch the path so that the analog audio signal, which is input from the line-in terminal 19, may bypass the sound controller 50 and go to the speaker amplifier 54 (block A8).

After the change-over of the analog switch 53 is completed, the EC/KBC 45 releases the mute state of the speaker amplifier 54 by the mute signal S3 (block A9).

In the speaker amplifier power-on mode, for example, if music is played back by the audio player 25 that is connected to the line-in terminal 19, the analog audio signal of the music is input to the speaker amplifier 54 via the line-in terminal 19 and analog switch 53. Since the speaker amplifier 54 is supplied with the A power from the power supply circuit 46, the speaker amplifier 54 can amplify the analog audio signal and output the music from the speakers 18. At this time, the personal computer 10 is in the standby state, and no power is supplied to the modules which are not associated with the audio output function.

On the other hand, if a transition to the power-off state is instructed by the user at the time of power-on (Yes in block A1), the EC/KBC 45 causes the power supply circuit 46 to turn off the power supply of the P power and B power. Specifically, if the transition to the power-off state is effected (m12 in FIG. 4), the power supply circuit 46 turns on the supply of only the S power (state M2 in FIG. 4). FIG. 10 shows a module to which power is supplied at the time of power-off without plug insertion. As shown in FIG. 10, since the backup of the main memory 32 is needless, the B power is not supplied in the state in which the power consumption is reduced to a minimum.

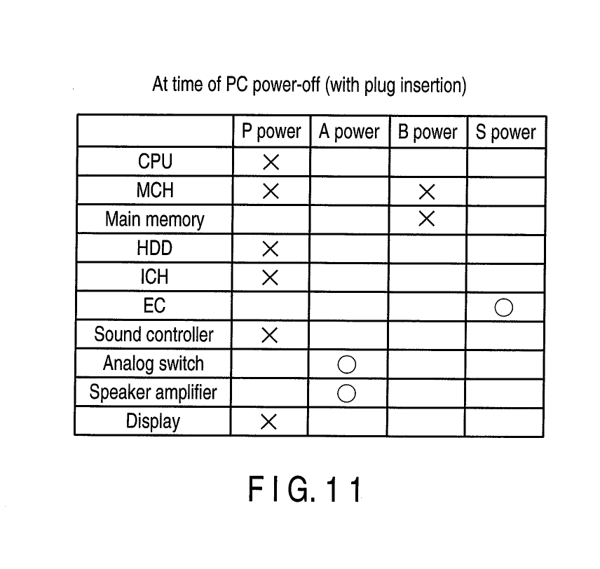

Like the above-described standby mode, if the plug is inserted in the line-in terminal 19 at the time of the power-off state (Yes in block A5), a transition to the speaker amplifier power-on mode is effected, and the audio which is output from the portable audio player 25 can be produced from the speakers (blocks A6 to A9). FIG. 11 shows modules to which power is supplied at the time of the power-off state with plug insertion. As shown in FIG. 11, aside from the S power, the A power is supplied to only the speaker amplifier 54 and analog switch 53 which are associated with the audio output function, and thus the power consumption is low.

In the case where the plug is removed from the line-in terminal 19 in the speaker amplifier power-on mode, the EC/KBC 45 detects the removal of the plug by the status signal S1 from the switch 52 (Yes in block A10) (m32 in FIG. 4). The EC/KBC 45 sets the speaker amplifier 54 in the mute state by the mute signal S3, prior to effecting a transition to the power-off state or standby state which is the state before the insertion of the plug in the line-in terminal 19 (block A11).

After the speaker amplifier 54 is set in the mute state, the EC/KBC 45 controls the analog switch 53 by the select signal S2, thereby changing the analog switch 53 over to the sound controller 50 side, and switching the path so that the analog audio signal, which is input from the line-in terminal 19, may go to the speaker amplifier 54 via the sound controller 50 (block A12).

The EC/KBC 45 causes the power supply circuit 46 to supply power in accordance with the power-off or the standby mode (block A13). Specifically, in the case of the power-off, only the S power is supplied (FIG. 10). In the case of the standby mode, the supply of the B power and S power is turned on (FIG. 8). In other words, the supply of the A power to the analog switch 53 and speaker amplifier 54 is turned off.

After the switching of the power supply is completed, the EC/KBC 45 releases the mute state of the speaker amplifier 54 by the mute signal S3 (block A14).

If the power button switch 14 is pressed in the speaker amplifier power-on mode and the power-on is instructed by the user (Yes in block A15), the EC/KBC 45 sets the speaker amplifier 54 in the mute state by the mute signal S3 (block A16).

After the speaker amplifier 54 is set in the mute state, the EC/KBC 45 causes the power supply circuit 46 to turn on the power supply of all the S power, B power, P power and A power (state M1 in FIG. 4), thereby to effect a transition to the power-on state (m31 in FIG. 4).

In addition, the EC/KBC 45 controls the analog switch 53 by the select signal S2, and switches the path to the sound controller 50 side so that the analog audio signal, which is input from the line-in terminal 19, may go to the speaker amplifier 54 via the sound controller 50 (block A18).

After the change-over of the analog switch 53 is completed, the EC/KBC 45 releases the mute state of the speaker amplifier 54 by the mute signal S3 (block A19).

As has been described above, in the personal computer 10 according to the embodiment, when the plug for connection of the portable audio player 25 is inserted in the line-in terminal 19 in the non-operative state, such as the power-off state or the standby mode, the power supply (A power) to the speaker amplifier 54 is turned on, and the analog audio signal, which is input from the line-in terminal 19, is input to the speaker amplifier 54, with the sound controller 50 being bypassed. Thereby, the sound by the audio signal, which is output from the portable audio player 25, can be produced from the speakers 18, without re-activating the personal computer 10.

In the above description, the line-in terminal 19 has been described as the terminal for audio signal input, but the line-in terminal 19 may be used also as the terminal for microphone connection. In this case, the power for a microphone is supplied to the line-in terminal 19 via the sound controller 50. Since the supply of the P power to the sound controller 50 is turned off in the power-off state or in the standby mode, the power for the microphone is not supplied to the line-in terminal 19.

In the above description, when the plug insertion is detected by the switch 52, the power supply circuit 46 turns on the supply of the A power (the power supply to the speaker amplifier 54 and analog switch 53) by the power supply circuit 46. Alternatively, the ON/OFF of the supply of the A power may be switched by other structure. For example, as shown in FIG. 2, a switch 60 may be provided for manually instructing the ON/OFF of the supply of the A power. For example, in the case where the personal computer 10 is in the non-operative state, if the EC/KBC 45 detects that the switch 60 has been turned on by the user's manual operation, the EC/KBC 45 sets the power supply circuit 46 to turn on the supply of the A power.

The switch 52, which is built in the line-in terminal 19, may be replaced with an independent switch which enables ON/OFF switching by the user's manual operation. The status signal S1 corresponding to the ON/OFF of this switch is input to the EC/KBC 45. In the case of using the portable audio player 25 by connecting it to the personal computer 10, the user can enable the audio output function by turning on this switch.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. (canceled)

2. (canceled)

3. (canceled)

4. (canceled)

5. (canceled)

6. (canceled)

7. An electronic apparatus comprising:
a terminal configured to input an audio signal from an external device;
an amplifier configured to amplify the audio signal which is output from the terminal; and
a first controller configured to operate when the electronic apparatus is in a non-operative state and to control a power supply circuit not to supply power to the amplifier when a plug is not inserted into the terminal and to control the power supply circuit to supply power when the plug is inserted into the terminal.

8. The electronic apparatus of claim 7, further comprising a second power supply system configured to supply power to the amplifier, the second power supply system being different from a first power supply system configured to supply power to each component of the electronic apparatus,
wherein the first controller controls the power supply circuit to supply power to the amplifier from the second power supply system when the plug is inserted into the terminal.

9. The electronic apparatus of claim 7, further comprising a switching module configured to switch between a first path connecting the terminal and the amplifier and a second path connecting the terminal and the amplifier via a second controller operated when the electronic apparatus is in an operative state,
wherein the first controller is configured to control the switching module to switch to the first path when the power supply circuit supplies power to the amplifier.

10. The electronic apparatus of claim 7, wherein the first controller is configured to instruct the amplifier to mute an audio signal output from the amplifier before the power supply circuit supplies power to the amplifier, and to release the amplifier from muting the audio signal after the power supply circuit starts to supply power to the amplifier.

11. A method of controlling a supply of power to an amplifier of an electronic apparatus, comprising:
when the electronic apparatus is in a non-operative state,
detecting by a controller whether a plug is inserted into a terminal configured to input an audio signal from an external device of the electronic apparatus; and
controlling a power supply circuit to supply power to the amplifier by a second power supply system different from a first power supply system configured to supply power of each component of the electronic apparatus, when the plug is inserted into the terminal.

12. The method of claim 11, wherein the controller is configured to instruct the amplifier to mute an audio signal which is output from the amplifier before the power supply circuit supplies power to the amplifier, and to release the amplifier from muting the audio signal after the power supply circuit starts to supply power to the amplifier.

13. An electronic apparatus comprising:
a speaker;
a terminal configured to input an audio signal from an external device via a plug connected to the external device when the plug is inserted into the terminal;
an amplifier configured to amplify the audio signal which is output from the terminal and output sound from the speaker when the amplifier is supplied with power;
a power supply circuit configured to supply power to the amplifier;
a first switch configured to output a signal to instruct the power supply circuit to supply power to the amplifier when the first switch is turned on; and
a first controller configured to operate when the electronic apparatus is both in an operative state and in a non-operative state, and to control the power supply circuit to supply the power to the amplifier if the first switch outputs the signal when the electronic apparatus is in the non-operative state.

14. The electronic apparatus of claim 13, wherein the power supply circuit comprises a power supply system configured to supply power to the amplifier, and turns on power supply via the power supply system in accordance with control by the first controller.

15. The electronic apparatus of claim 14, further comprising a second switch configured to switch one of a first path which connects the terminal and the amplifier, and a second path which connects the terminal and the amplifier via a second controller configured to operate when the electronic apparatus is in an operative state,
wherein the first controller is configured to control the second switch to switch the first path when the electronic apparatus is in the operative state and the power supply circuit supplies power to the amplifier.

16. The electronic apparatus of claim 13, wherein the first controller is configured to instruct the amplifier to mute the sound output from the amplifier before the power supply circuit supplies power to the amplifier, and to release the amplifier from muting the sound after the power supply circuit starts to supply power to the amplifier.

17. The electronic apparatus of claim 13, wherein the first switch is turned on when the terminal receives the audio signal from the external device.

18. The electronic apparatus of claim 13, wherein the first switch is turned on by a user operation.
